(19) United States
(12) Patent Application Publication
(10) Pub. No.: US 2025/0119096 A1
(43) Pub. Date: Apr. 10, 2025

(54) SYSTEM AND METHOD USING ELECTRONIC LOAD FOR PHOTOVOLTAIC I-V CURVE TRACING

(71) Applicant: The Hong Kong University of Science and Technology, Hong Kong (CN)

(72) Inventors: Xuantong ZHOU, Hong Kong (CN); Changying XIANG, Hong Kong (CN)

(21) Appl. No.: 18/806,742

(22) Filed: Aug. 16, 2024

Related U.S. Application Data
(60) Provisional application No. 63/589,025, filed on Oct. 10, 2023.

(51) Int. Cl. H02S 50/10; G01R 19/165; H02S 40/30

(52) U.S. Cl. CPC H02S 50/10; G01R 19/16519; H02S 40/30

(57) ABSTRACT

A system includes a measurement module, an industrial I/O expansion module, an SBC module, and a user interface module. The measurement module provides a platform for connecting a PV panel module for current and voltage measurement. The measurement module comprises a voltage sensor, a current sensor, and a MOSFET. The PV panel module and the current sensor are connected in series, and a series combination of the PV panel module and the current sensor is connected in parallel with the voltage sensor as well as the MOSFET. The industrial I/O expansion module is coupled with the measurement module for conversion of analog signals to digital signals. The SBC module obtains current and voltage readings from the measurement module via the industrial I/O expansion module. The user interface module is coupled with the SBC module and provides a user interface, allowing users to operate a measurement process.

### CROSS-REFERENCE TO RELATED APPLICATIONS

The present application claims priority from the U.S. provisional patent application Ser. No. 63/589,025 filed 10 Oct. 2023, and the disclosures of which are incorporated herein by reference in their entirety.

### TECHNICAL FIELD

The present invention generally relates to techniques for photovoltaic I-V curve tracing. More specifically, the present invention relates to systems and methods using an electronic load for photovoltaic I-V curve tracing.

### BACKGROUND

Plotting the I-V (current-voltage) and P-V (power-voltage) curves for a photovoltaic (PV) panel is a core technique to demonstrate its characteristics. These curves provide a comprehensive view of the panel's performance under varying conditions, including key parameters such as the open-circuit voltage, short-circuit current, and the maximum power point. By analyzing these curves, one can determine the efficiency and suitability of the PV panel for different scenarios, making this technique required in both research and practical implementations of solar energy systems.

There are six fundamental methods to measure a PV panel's I-V curve: using a variable resistor, a capacitive load, an electronic load, a bipolar power amplifier, a four-quadrant power supply, and a DC-DC converter. Each of these methods offers different advantages and is chosen based on the desired requirements.

For example, a variable resistor is often used for its simplicity and cost-effectiveness, while an electronic load provides precise control and is ideal for detailed performance analysis. Capacitive loads are useful for dynamic testing, and bipolar power amplifiers are employed for their ability to handle both sourcing and sinking of current. A four-quadrant power supply is particularly versatile, capable of operating in all four quadrants of the I-V plane, thus supporting a wide range of test conditions. DC-DC converters are essential in scenarios requiring efficient power management and conversion, ensuring that the PV panel operates close to its maximum power point.

The choice of method depends on the accuracy, complexity, and specific testing requirements. Therefore, there is a need for optimization in the measurement methods, which can provide comprehensive coverage of the PV panel's I-V characteristics.

### SUMMARY OF INVENTION

It is an objective of the present invention to provide an apparatus and a method to address the aforementioned issues in the prior arts.

In accordance with one aspect of the present invention, a system for photovoltaic I-V curve tracing is provided. The system includes a measurement module, an industrial I/O expansion module, a single-board computer (SBC) module, and a user interface module. The measurement module provides a platform for connecting a photovoltaic (PV) panel module for current and voltage measurement using an electronic load. The measurement module comprises a voltage sensor, a current sensor, and a metal-oxide-semiconductor field-effect transistor (MOSFET) serving as the electronic load. The PV panel module and the current sensor are connected in series, and a series combination of the PV panel module and the current sensor is connected in parallel with the voltage sensor as well as the MOSFET. The industrial I/O expansion module is coupled with the measurement module for conversion of analog signals to digital signals. The SBC module is configured to obtain current and voltage readings from the measurement module via the industrial I/O expansion module. The user interface module is coupled with the SBC module and provides a user interface, allowing at least one user to operate a measurement process and obtain visual measurement results.

In accordance with one aspect of the present invention, a method for arranging a system for photovoltaic I-V curve tracing is provided. The method includes steps as follows: providing a measurement module providing a platform for connecting a PV panel module for current and voltage measurement using an electronic load, wherein the measurement module comprises a voltage sensor, a current sensor, and a MOSFET serving as the electronic load; connecting the PV panel module and the current sensor in series; connecting a series combination of the PV panel module and the current sensor in parallel with the voltage sensor as well as the MOSFET; coupling an industrial I/O expansion module with the measurement module for conversion of analog signals to digital signals; coupling an SBC module with the industrial I/O expansion module such that the SBC module is able to obtain current and voltage readings from the measurement module via the industrial I/O expansion module; and coupling a user interface module with the SBC module, such that the user interface module is able to provide a user interface, allowing at least one user to operate a measurement process and obtain visual measurement results.

In accordance with one aspect of the present invention, a method for photovoltaic I-V curve tracing is provided. The method includes steps as follows: providing the system as afore mentioned; and displaying the visual measurement results comprising a graph with a plotting of I-V and P-V curves for the PV panel module.

By the above configuration, the system of the present invention employs a MOSFET as the electronic load for measurement because the linear MOSFET's operation is influenced by a scan signal with a low frequency and a sufficiently large amplitude, which enables comprehensive coverage of the range of the PV panel's I-V characteristics. The basic principle of the measurement involves utilizing Raspberry Pi 4B as the central processing unit (CPU) to transmit signals for regulating the gate-source voltage (V_{GS}) of the MOSFET while simultaneously obtaining current and voltage readings from sensors. The process of converting analogue signals to digital signals between the Raspberry Pi and the measurement circuit has been facilitated by an Industrial Automation I/O Card for Raspberry Pi. In order to facilitate the display of the measurement progress and results, a Graphical User Interface (GUI) has been developed using PyQt5. The model's portability and flexibility make it suitable for educational purposes, serving as a research and educational tool to demonstrate the development of I-V curves.

### BRIEF DESCRIPTION OF DRAWINGS

Embodiments of the invention are described in more details hereinafter with reference to the drawings, in which:

FIG. 1 depicts a schematic diagram of an architecture of a system for photovoltaic I-V curve tracing according to one embodiment of the present invention;

FIG. 2 depicts a schematic diagram of an architecture of the measurement module according to one embodiment of the present invention;

FIG. 3 depicts a circuit schematic diagram of the measurement principle of the measurement module according to one embodiment of the present invention;

FIG. 4 depicts the characteristics of a PV panel module at STC and the characteristics of a MOSFET according to one embodiment of the present invention;

FIG. 5A depicts a wiring configuration for the voltage sensor according to one embodiment of the present invention;

FIG. 5B which shows a circuit diagram of the voltage sensor according to one embodiment of the present invention;

FIG. 6 depicts a circuit connection configuration for the current sensor according to one embodiment of the present invention;

FIG. 7A shows a N-channel MOSFET for the MOSFET according to one embodiment of the present invention;

FIG. 7B shows output characteristics for the MOSFET when TC=25° C. according to one embodiment of the present invention;

FIG. 7C shows a circuit diagram for the MOSFET according to one embodiment of the present invention;

FIG. 8 shows a schematic graph for a sawtooth wave as a sweeping signal to generate V_{GS} according to one embodiment of the present invention

FIG. 9A shows a schematic diagram for the power supply according to one embodiment of the present invention;

FIG. 9B shows a filter circuit diagram of the AC/DC converter according to one embodiment of the present invention;

FIG. 9C shows a filter circuit diagram of the DC/DC converter according to one embodiment of the present invention;

FIG. 10 depicts a flow chart of the measurement algorithm according to one embodiment of the present invention;

FIG. 11 depicts a schematic diagram for the GUI of the PV panel's I-V curve measurement based on PyQt5 according to one embodiment of the present invention;

FIG. 12A is an exemplary diagram showing GUI which displays complete I-V and P-V curves in a manual mode; and

FIG. 12B is an exemplary diagram showing GUI which displays complete I-V and P-V curves in an auto mode.

### DETAILED DESCRIPTION OF THE INVENTION

In the following description, systems and methods using an electronic load for photovoltaic I-V curve tracing and the likes are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

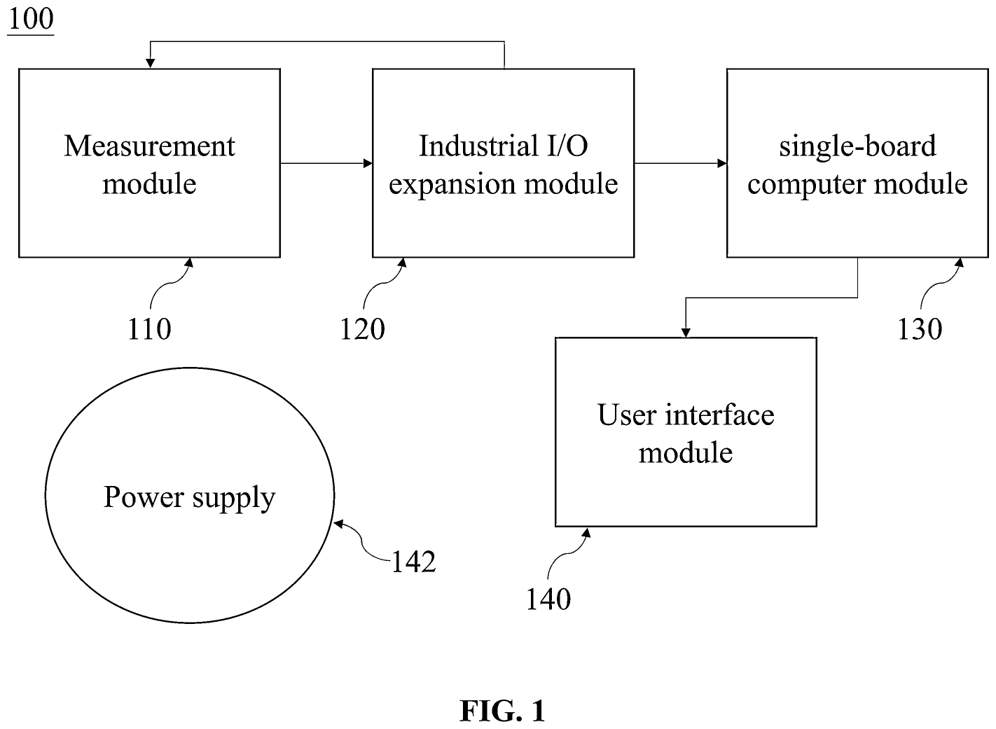

FIG. 1 depicts a schematic diagram of an architecture of a system 100 for photovoltaic I-V curve tracing according to one embodiment of the present invention. The system 100 includes a measurement module 110, an industrial I/O expansion module 120, a single-board computer (SBC) module 130, and a user interface module 140.

The measurement module 110 provides a platform for connecting a photovoltaic (PV) panel module for current and voltage measurement using an electronic load. The industrial I/O expansion module 120 is coupled with the measurement module 110 for conversion of analog signals to digital signals. The SBC module 130 is configured to obtain current and voltage readings from the measurement module 110 via the industrial I/O expansion module 120, enabling programmatic control of the measurement process. The user interface module 140 is coupled with the SBC module 130 and provides a user interface, allowing the user to operate the measurement process and obtain the visual measurement results. The following descriptions are provided for further explanations for each module.

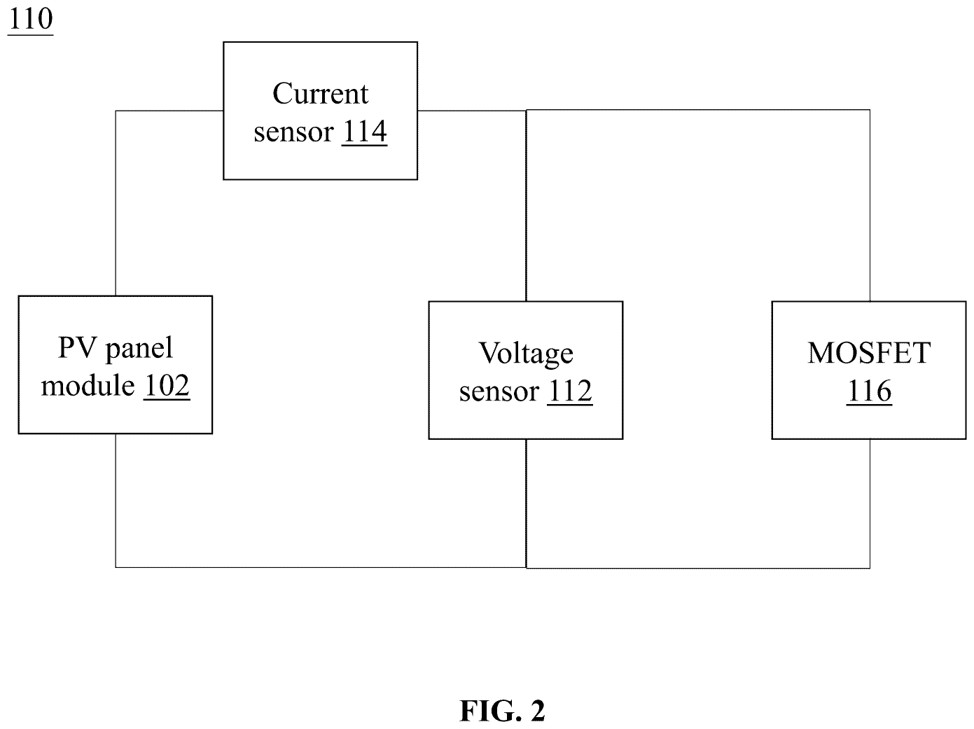

FIG. 2 depicts a schematic diagram of an architecture of the measurement module 110 according to one embodiment of the present invention. The measurement module 110 includes a voltage sensor 112, a current sensor 114, and a metal-oxide-semiconductor field-effect transistor (MOSFET) 116 serving as an electronic load. The measurement for photovoltaic I-V curve tracing is performed on a PV panel module 102. The PV panel module 102 and the current sensor 114 are connected in series. This series combination is then connected in parallel with the voltage sensor 112 as well as the MOSFET 116. Accordingly, the voltage sensor 112 and the MOSFET 116 are also connected in parallel with each other.

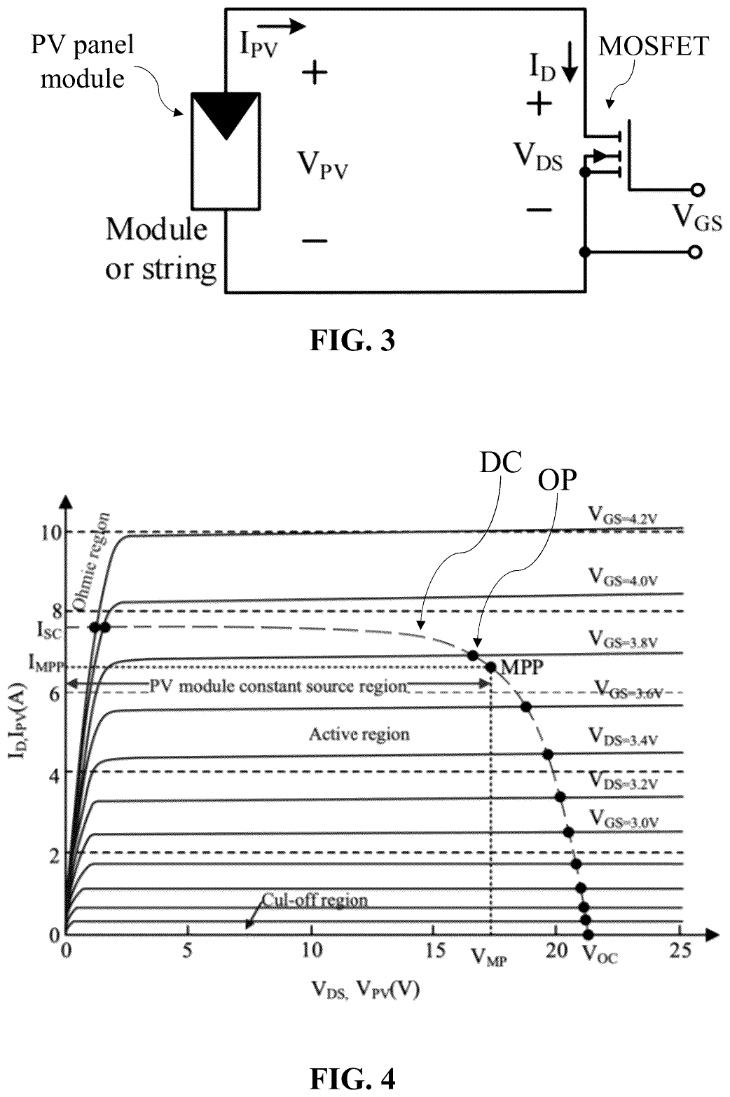

In this regard, FIG. 3 depicts a circuit schematic diagram of the measurement principle of the measurement module 110 according to one embodiment of the present invention; and FIG. 4 depicts the characteristics of a PV panel module at standard test conditions (STC) and the characteristics of a MOSFET according to one embodiment of the present invention.

In the illustration of FIG. 3, for explaining the measurement principle, a fundamental circuit is provided for testing of a PV panel module (e.g., a PV panel module or string) through utilization of a MOSFET as an electronic load. MOSFET has a drain coupled with an anode of the PV panel module and a source coupled with a cathode of the PV panel module. MOSFET has a gate serving as a control terminal. For the MOSFET, V_{GS} is a gate-source voltage, V_{DS} is a drain-source voltage, and ID is a drain current. V_{PV} is an output voltage of the PV panel module, I_{PV} is an output current, I_{SC} is a short circuit current and V_{OC} is an open circuit voltage.

The illustration of FIG. 4 displays the characteristics of a MOSFET through the graphical representation of individual I_{D}-V_{DS} curves (see the sloid-line curves) corresponding to a specific gate-source voltage (V_{GS}). This illustration also depicts the I_{PV}-V_{PV} curve of a PV panel module, as indicated by the dot-line curve DC. The operating point(s) OP is determined by the intersection of the PV module characteristic and the MOSFET characteristic at a specific voltage V_{GS}. By applying an appropriate signal to sweep V_{GS}, the MOSFET's operating point can sweep the I_{PV}-V_{PV} curve from V_{OC} to I_{SC}. The MOSFET will remain in the OFF state as long as its V_{GS} remains below the threshold voltage (Vth). When V_{GS} surpasses Vₜₕ, the PV panel module can function within its active region, where the ID or IPV increases in an almost linear manner with V_{GS}.

Regarding the PV panel module, in regions where V_{PV} exceeds the voltage at the maximum power point (V_{MPP}) depicted in FIG. 2, the voltage V_{PV} exhibits sensitivity towards minor fluctuations in current (I_{PV}) and consequently towards minor fluctuations in V_{GS}. The rapid movement of the operating point in this region can be attributed to its high sensitivity, which necessitates the creation of a suitable sweeping signal for the generation of voltage V_{GS}.

From the above, it is clear that using a MOSFET for photovoltaic I-V curve tracing is feasible, achieving tracking the photovoltaic I-V curve of the PV panel module on the voltage and current characteristic graph. Furthermore, based on using the measurement principle stated herein, the following descriptions provide the selected hardware configuration and software setup, so as to implement a flexible and portable measurement platform.

Referring to FIG. 2 again, which shows a measurement circuit, the voltage is measured directly at an output terminal of the PV panel module 102. The measurement conducted by the architecture of the measurement module 110 accurately represents the operations of the PV panel module 102. In one embodiment, the PV panel module 102 applies a silicon mono-crystalline SPV module (e.g., M010-12V). Table I displays its electrical specification at Standard Test Condition (STC, Irradiance 1000 W/m², Module temperature 25° C., AM=1.5) for the PV panel module 102.

TABLE I
Electrical and Mechanical Characteristics
of the PV Module (M010-12 V) in STC

| | | | |
|---|---|---|---|
| Electrical | Voltage at max power (Vₘₚ) | 18.5 | V |
| data at STC | Current at max power (Iₘₚ) | 0.55 | A |
| | Voltage at open circuit (V_{oc}) | 23.2 | V |
| | Short circuit current (I_{sc}) | 0.57 | A |
| | Rated power | 10 | W |
| Mechanical data | Weight | 1.20 | kg |
| | Dimensions | 355*252*25 | mm |

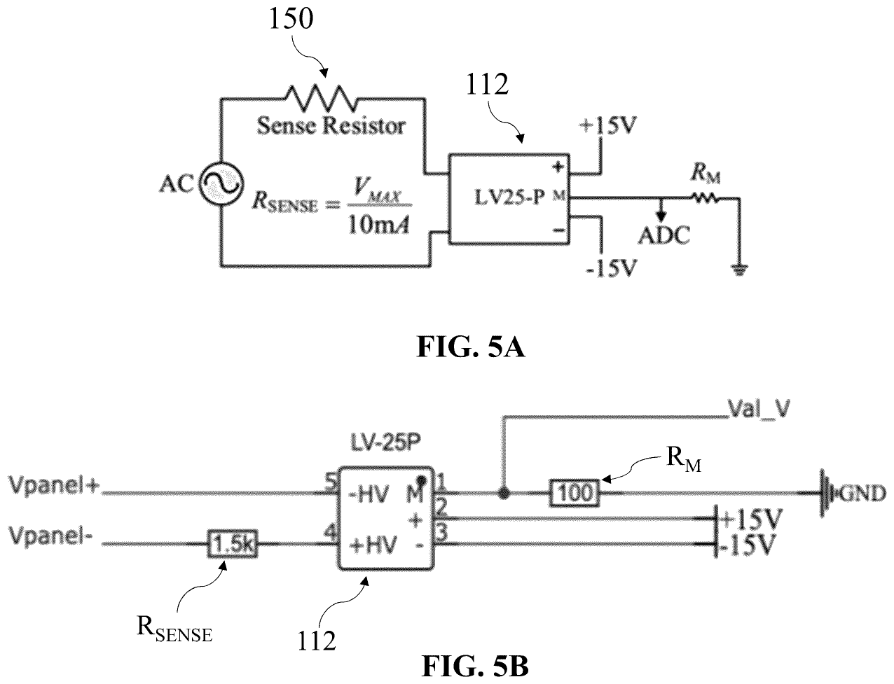

In one embodiment, a LEM voltage sensor is chosen for the voltage sensor 112 is to quantify the voltage; in this regard, LEM LV 25-P is a type of voltage sensor 112 that utilizes the hall-effect principle. The sensing voltage and signal output are separated by galvanic isolation. The voltage sensor 112 has the capacity to measure voltage levels of up to 600 V. FIG. 5A depicts a wiring configuration for the voltage sensor 112 according to one embodiment of the present invention. The voltage sensor 112 has the capability to measure both AC and DC voltages, and requires balanced power input. The current output of the voltage sensor 112 is dependent upon the voltage detected at its input. The voltage at the resistor terminals linked to the under-voltage side of the voltage sensor 112 can be conveniently measured by connecting it to any of the microcontroller's analogue inputs, thereby facilitating the measurement of the input voltage.

In one embodiment, the measurement module 110 further includes a supply voltage for the voltage sensor 112 within a range of ±15 V. In order to restrict the current prior to its input into the voltage sensor 112, the measurement module 110 further includes a sense resistor (R_{SENSE}) 150 for the voltage sensor 112. The process for determining the appropriate sense resistor involves dividing the maximum sensing voltage, which is equivalent to the PV panel's open circuit voltage, by a current of 10 mA. The 10 mA is the nominal current rms (I_{PN}) for the voltage sensor 112 based on tolerance requirements. Given that the voltage level under consideration in some embodiments does not surpass 24V, the value of the sense resistor is:

$${R}_{sense} = \frac{{V}_{OC}}{{I}_{PN}} = \frac{24 V}{10 mA} = 2.4 k Ω$$

A fixed resistance of 1.5 kΩ can be selected as R_{SENSE} (i.e., which is for the sense resistor 150). The output of voltage sensor 112 is current. However, the ADC module only reads the voltage signal instead of the current signal. In one embodiment, the measurement module 110 further includes a ground resistor, denoted as R_{M}, is positioned at the output terminal with the purpose of transforming the current into a corresponding voltage signal. According to the datasheet, R_{M} can be chosen as 100 Ω. The circuit diagram of the voltage sensor 112 for LV 25-P, in some embodiments, is shown in FIG. 5B which shows a circuit diagram of the voltage sensor 112 according to one embodiment of the present invention.

Since the turns ratio of the voltage sensor 112 for LEM LV25-P is 2500:1000, the relationship between the measured voltage (Uₘ) and input voltage (Uᵢₙ) is:

$$\frac{{U}_{in}}{{R}_{sense}} \times \frac{2500}{1000} \times {R}_{M} = {U}_{m}$$

In one embodiment, by substituting R_{SENSE}=1500 Ω and R_{M}=100 Ω into the equation above, the relationship between Uₘ and Uᵢₙ is:

$${U}_{in} = 6 \times {U}_{m}$$

Accordingly, as shown in FIG. 5B, the voltage sensor 112 is coupled to the negative voltage pole of the PV panel module 102 via the R_{SENSE} of 1500 Ω and to the ground via the R_{M} of 100 Ω.

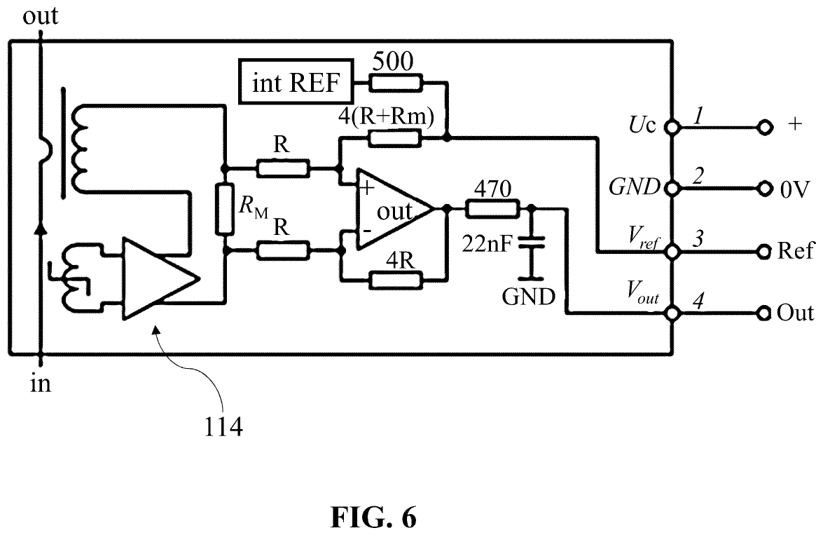

FIG. 6 depicts a circuit connection configuration for the current sensor 114 according to one embodiment of the present invention. In one embodiment, the current sensor 114 applies the CTSR 0.6-P sensor which is manufactured by LEM to the purpose of current sensing. It is a closed loop current transducer that operates with exceptional precision and minimal offset drift in response to changes in temperature. The current sensor 114's measurement range is ±850 mA, accompanied by a maximum sensitivity error of 0.7% and a linearity error of 0.4%-1.3%. The current sensor 114 can measure DC, AC and pulsed currents, with galvanic separation between the primary circuit and the secondary circuit.

In the illustration of FIG. 6, U_{c} is the power supply, which is 5 V. The output of the current sensor 114 is voltage, labeled as Vₒᵤₜ. The labeled V_{ref} can be empty in some embodiments. To enhance precision in the current measurement, a selection is made to utilize two turns of the output cable from the PV panel, of which the sensitivity is 0.48 V/100 mA; that is to say, 4.8 V/A. The internal reference of the current sensor 114 is 2.5 V. Therefore, the equation shown below is obtained for calculating the PV panel's current:

$${I}_{in} = \frac{{V}_{out} = 2.5}{4.8}$$

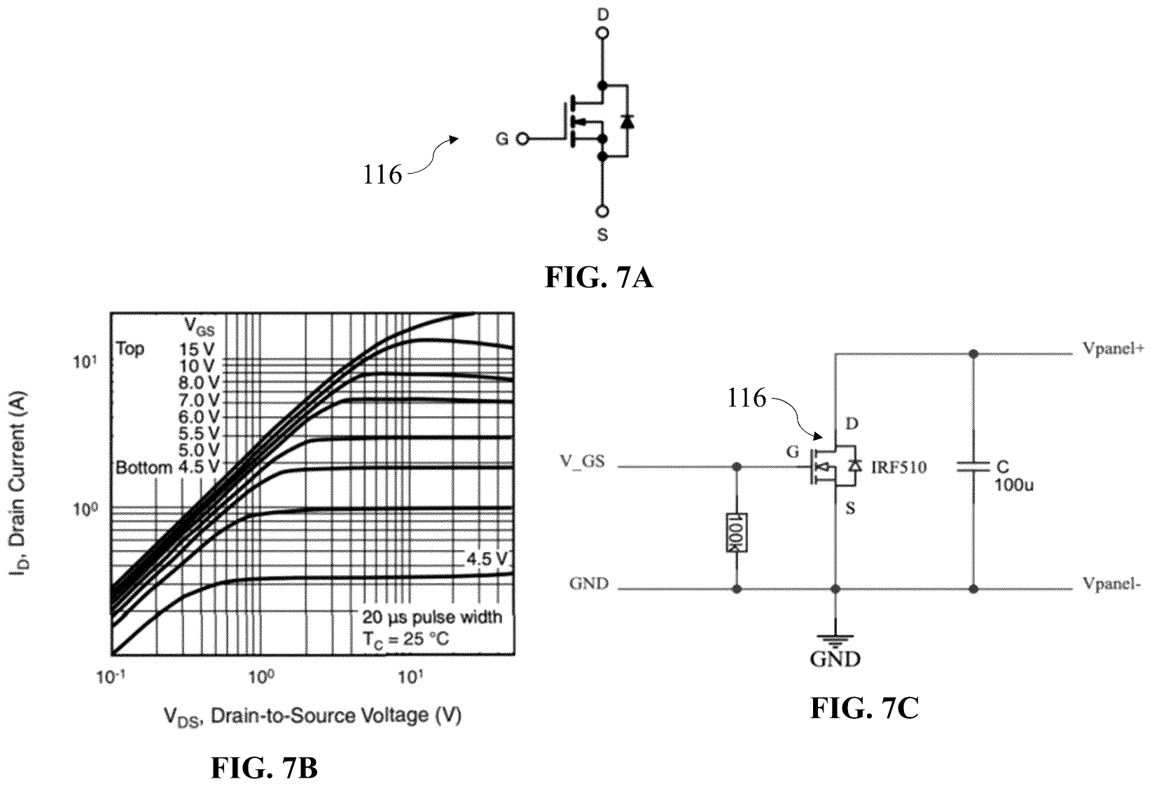

FIG. 7A shows a N-channel MOSFET for the MOSFET 116 according to one embodiment of the present invention. In one embodiment, the MOSFET 116 applies an N-Channel MOSFET, such as IRF510, as the electronic load. In this regard, for the MOSFET 116, the range of its gate-source voltage (V_{GS}) is ±20 V, while the maximum drain-source voltage (V_{DS}) is 100V. At a temperature of 25° C., the continuous drain current (ID) is restricted to 5.6 A, while at a temperature of 100° C., it is limited to 4.0 A.

FIG. 7B shows output characteristics for the MOSFET 116 when T_{C}=25° C. according to one embodiment of the present invention. In the illustration, it can be observed that, for V_{GS} values less than 5 V, the corresponding I_{D} values are less than 1 A. In one embodiment, given that the short circuit current (I_{SC}) of the PV panel is 0.57 A, it is optional to select a gate-source voltage (V_{GS}) within the range of 3-5 V for the MOSFET 116 for the purpose of measuring/tracing the I-V curve of the PV panel.

FIG. 7C shows a circuit diagram for the MOSFET 116 according to one embodiment of the present invention. As the drain contact may attach to the metallic surfaces of the package in the MOSFET 116, it is optional to electrically isolate the MOSFET 116 and mount it onto a suitable heat sink. In one embodiment, the gate G and the source S of the MOSFET 116 can be connected in parallel with a resistor of 100 kΩ and jointly coupled to the gate-source voltage supply V_{GS} (the gate G is coupled with a gate-source voltage supply and the source S is coupled with a ground potential terminal). The drain D and the source S of the MOSFET 116 can be connected in parallel with a capacitor of 100 uF, and then are connected to terminals Vpanel+ and Vpanel− (i.e., the positive and negative terminals of the PV panel), respectively.

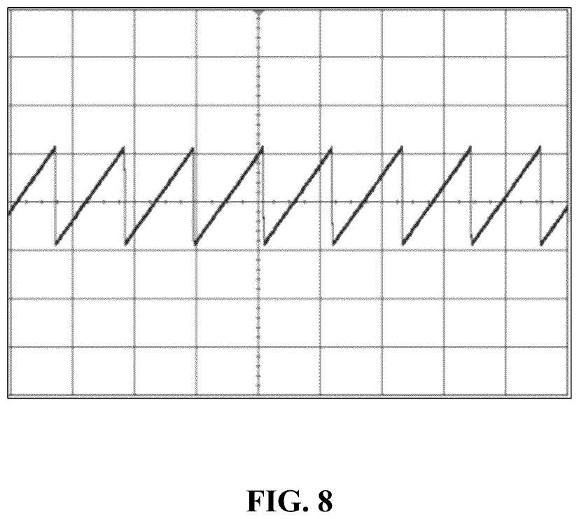

FIG. 8 shows a schematic graph for a sawtooth wave as a sweeping signal to generate V_{GS} according to one embodiment of the present invention. Referring to FIG. 1 and FIG. 8, as discussed above, the voltage sensor 112 and the current sensor 114 may employ LV 25-P and CTSR 0.6-P sensors for the purpose of voltage and current measurement. In one embodiment, the single-board computer module 130 applies a Raspberry Pi 4B for processing digital signals. In this regard, the sensors for voltage and current may pose a challenge as they generate analogue signals, whereas the Raspberry Pi is only capable of processing digital signals.

To solve this problem, the industrial I/O expansion module 120 applies an industrial automation I/O card for the Raspberry Pi, which offers four analogue inputs with a range of 0-10 V or ±10 V, as well as four analogue outputs with a range of 0-10 V. The communication protocol utilized for the interface between the industrial I/O expansion module 120 and the single-board computer module 130 is the Inter Integrated Circuit (I2C) protocol.

During the operation of the industrial I/O expansion module 120, the industrial I/O expansion module 120 can collect data of 0-10 V or ±10 V analog inputs from the voltage sensor 112 and the current sensor 114 of the measurement module 110. As shown in FIG. 8, a sawtooth wave with a voltage range of 3-5 V is produced through the 0-10 V analog output from the industrial I/O expansion module 120 as a sweeping signal to generate V_{GS} (gate-source voltage).

The industrial I/O expansion module 120 will first send sweeping signals through the 0-10V analogue output to generate V_{GS} ranging between 3-5V and the step is 0.01V for the MOSFET 116 of the measurement module 110. In one embodiment, the step for voltage is adjustable when coding. Thus, a total of 2000 V_{GS} values can be obtained. Each Vas value corresponds to a pair (current I, voltage V) of the PV panel (i.e., the PV panel module 102). The voltage and current data are transmitted into the 0-10V or ±10V analogue inputs of the industrial I/O expansion module 120. The single-board computer module 130 (e.g., Raspberry Pi 4B) serves as a microprocessor computer that is utilized as a CPU for the purposes of data logging, data storage, and curve plotting. The user interface module 140 may be a laptop serving the purpose of displaying.

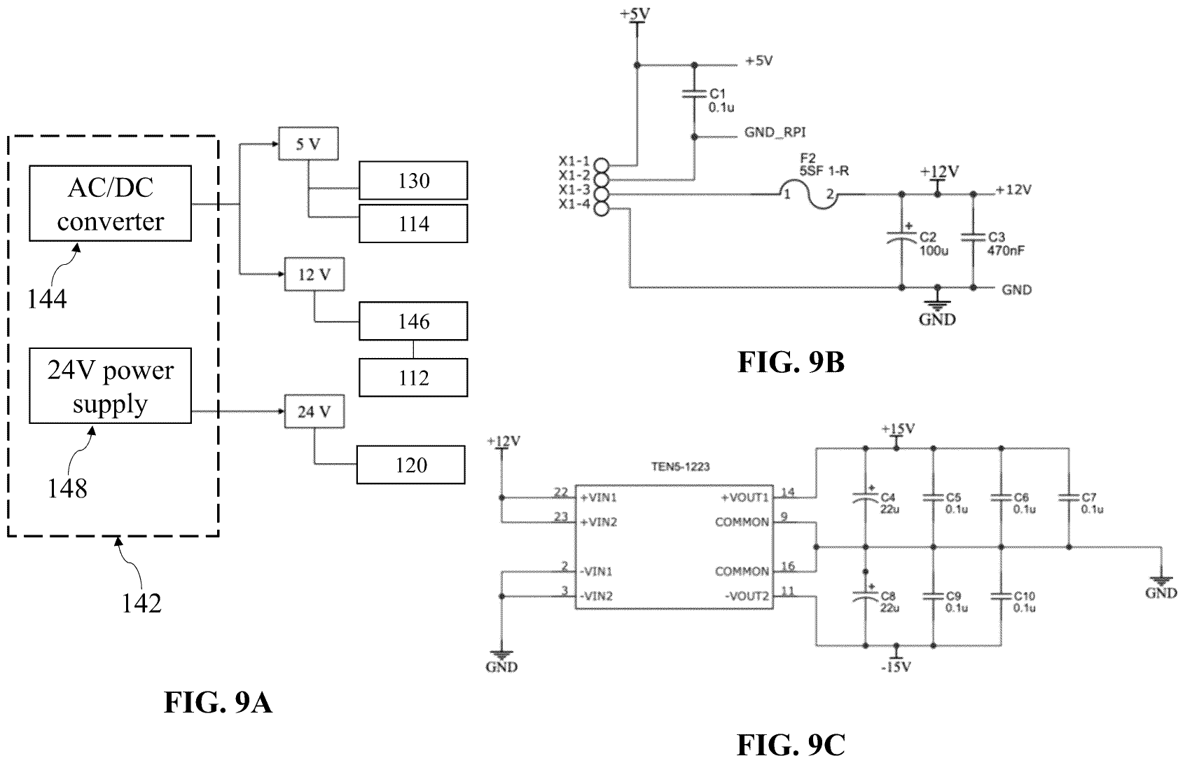

The system 100 further includes a power supply 142. FIG. 9A shows a

schematic diagram for the power supply 142 according to one embodiment of the present invention. In the power supply 142, a power circuit is linked to an AC/DC converter 144 (e.g., Mean Well RD-50A), which has the capability to transform 88-264 VAC into isolated 5 VDC and 12 VDC. The single-board computer module 130 (Raspberry Pi) and the current sensor 114 (CTSR 0.6-P) utilize the 5 VDC output and the 12 VDC output is used by a DC/DC converter 146 (e.g., TEN 5-1223), which provides ±15 V to the voltage sensor 112 (LV 25-P). Moreover, the industrial I/O expansion module needs a 24 V power supply 148 (e.g., TCL 060-124).

FIG. 9B shows a filter circuit diagram of the AC/DC converter 144 according to one embodiment of the present invention. In one embodiment It is optional to filter the output voltage of the AC/DC converter 144 prior to its connection to the measurement module 110. In the illustration of FIG. 9B, the label X1-1, X1-2, X1-3 and X1-4 are connectors which are connected to +Vout1, GND, +Vout2 and GND of the AC/DC converter 144, respectively. The label is a type of fuse designed to safeguard the circuit. FIG. 9C shows a filter circuit diagram of the DC/DC converter 146 according to one embodiment of the present invention. For the same reason, in one embodiment, it is optional to design a filter circuit for the DC/DC converter 146, of which the output voltage is ±15 V, and it supplies the voltage sensor 112.

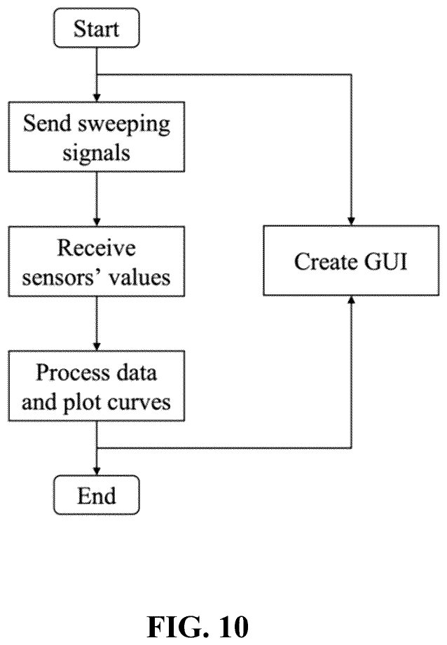

FIG. 10 depicts a flow chart of the measurement algorithm according to one embodiment of the present invention. The code composition can be made to facilitate the operation of the measurement. In this regard, it is advantageous to generate a Graphical User Interface (GUI) to display the measurement progress and outcomes via the user interface module 140. In one embodiment, PyQt5 is a collection of Python applications written in Python language and utilizes the graphical program framework Qt5. These applications are compatible with Linux operating systems and can be executed on the single-board computer module 130 (Raspberry Pi). The PyQt framework offers a range of tools that enable the creation of user interfaces capable of interfacing with SQL databases, 2D and 3D graphics, network communication, multimedia, and other functionalities.

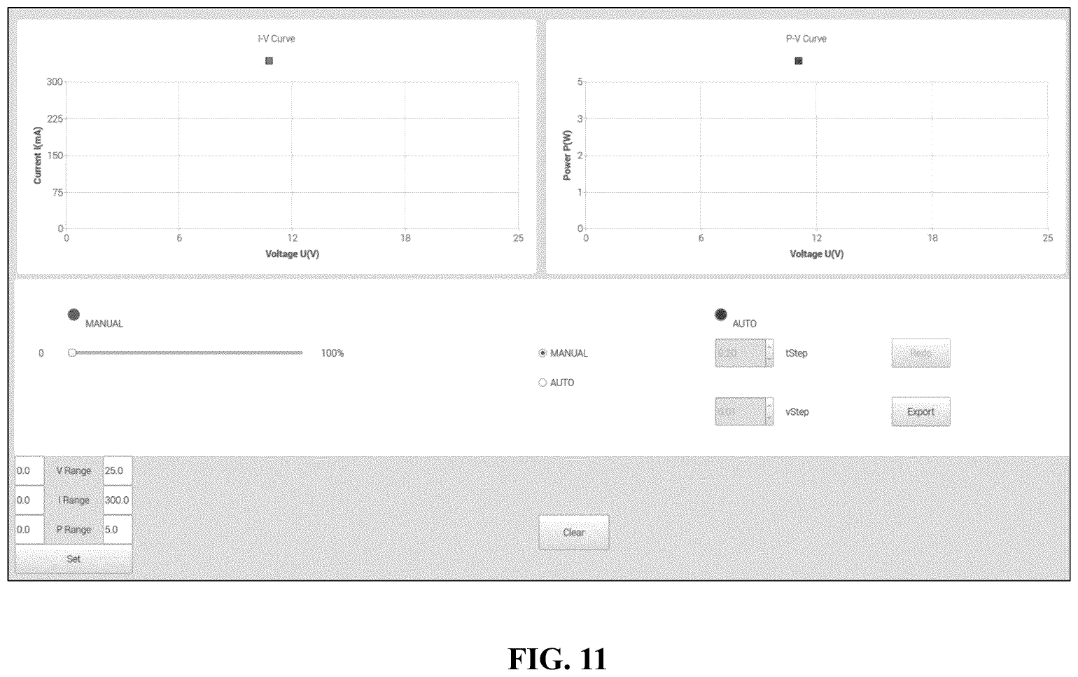

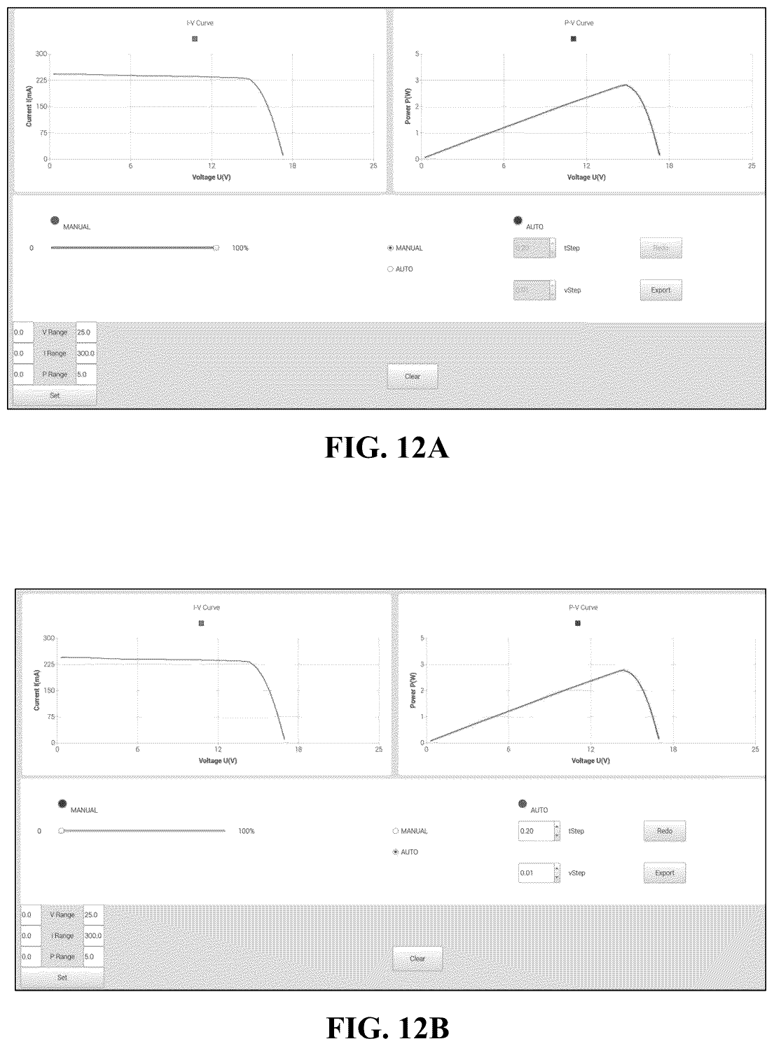

FIG. 11 depicts a schematic diagram for the GUI of the PV panel's I-V curve measurement based on PyQt5 according to one embodiment of the present invention. In one embodiment, the GUI based on PyQt5 can be displayed for the user via the user interface module 140. For example, users can see a window as depicted by FIG. 11 user via the user interface module 140. There are two modes for the measurement controlling, manual mode and auto mode. When the “MANUAL” button is on for the manual mode, it enables the user to regulate the V_{GS} alteration by manipulating the slider within the range of 0 (i.e., 3V) to 100% (i.e., 5V) to generate the I-V and P-V curves. When the “AUTO” button is on, V_{GS} can undergo automatic modification, in which the value step and time step can be set through “vStep” and “tStep” functions respectively in the user interface module 140. In one embodiment, values for these parameters are vStep=0.01V, and tStep=0.2 s, in which increasing the value of vStep or decreasing the value of tStep may lead to a higher plotting speed. The button “REDO” can clear and redraw the curves. The “EXPORT” button enables the exportation of current and voltage values to a CSV document. When pressing the “Clear” button, it removes all the contents from the user interface module 140. Furthermore, the settings located in the lower left corner have the ability to modify the range of values for the coordinate axes. By this configuration, in combination with the system 110 as previously described, the plotting of I-V and P-V curves for the PV panel module 102 can be obtained. In one embodiment, the user interface module 140 is further configured to display the visual measurement results comprising a graph with the I-V and P-V curves for the PV panel module 102. For example, FIG. 12A is an exemplary diagram showing GUI which displays complete I-V and P-V curves in a manual mode; and FIG. 12B is an exemplary diagram showing GUI which displays complete I-V and P-V curves in an auto mode. Additionally, similar to the illustration in FIG. 4, the curves for the characteristics of the MOSFET 116 at different gate-source voltages are also present on the graph, helping users better understand the composition or the structure of the obtained I-V and P-V curves.

Compared with a device that utilizes a capacitor to test the PV panel's I-V characteristic curve and works with data using Raspberry Pi and Analog Discovery 2, the capacitor can only be continuously charged and discharged, which means that the drawing of the I-V curve cannot be interrupted. Therefore, it is not possible to better demonstrate the process. Capacitors store electrical charge, and when the voltage across the capacitor changes, it results in a transient response, i.e., a temporary flow of current. This transient behavior can complicate the interpretation of the I-V curve, especially if the measurement setup does not account for these transients. To test the I-V curve of a capacitor accurately, one needs to consider the time factor. Capacitors take time to charge and discharge, and the I-V curve will vary depending on the rate at which the voltage changes. This makes the testing process more complex and time-consuming. When using a capacitor, the magnitude of the current depends on the rate of change of the voltage (dV/dt). This can make it challenging to precisely control the current value, leading to less accurate and repeatable measurements. Moreover, the Analog Discovery 2, an analog-to-digital converter, is more expensive than the Industrial Automation Card.

Compared with a device that chooses Arduino as the CPU to work with data, the present invention uses Raspberry Pi to draw an I-V (Current-Voltage) curve and thus offers several advantages over using an Arduino. Raspberry Pi has a more powerful processor compared to Arduino. This means the Raspberry Pi can perform complex calculations and data processing more efficiently. Drawing an I-V curve involves reading analog data from a sensor, processing it, and plotting the curve, which can be computationally intensive. Raspberry Pi's higher processing power ensures smoother and faster data handling. Raspberry Pi runs on a full-fledged operating system (usually Linux-based), which provides access to a wide range of programming languages, libraries, and tools. This makes it easier to develop, debug, and modify the code for drawing the I-V curve. On the other hand, Arduino uses its specific IDE and programming language, which might have some limitations for data manipulation and plotting. Raspberry Pi has built-in connectivity options, such as Ethernet, Wi-Fi, and USB ports. This allows users to easily transfer data to external devices, store the data remotely, or even upload it to the cloud for further analysis. Arduino, while capable of interfacing with sensors, might require additional modules or shields to enable similar connectivity options. Raspberry Pi can connect to various displays and has better graphics capabilities compared to Arduino. This makes it more suitable for real-time visualization of the I-V curve on a monitor or a graphical interface. Arduino, being more focused on microcontroller functionality, might not offer the same level of graphical capabilities. Raspberry Pi typically comes with more storage options, either through SD cards or onboard memory, compared to most Arduino boards. This allows for storing a larger amount of data and experimenting with various data logging techniques while drawing the I-V curve.

The functional units and modules of the processor and methods in accordance with the embodiments disclosed herein may be embodied in hardware or software. That is, the claimed processor may be implemented entirely as machine instructions or as a combination of machine instructions and hardware elements. Hardware elements include, but are not limited to, computing devices, computer processors, or electronic circuitries including but not limited to application specific integrated circuits (ASIC), field programmable gate (FPGA), microcontrollers, and other programmable logic devices configured or programmed according to the teachings of the present disclosure. Computer instructions or software codes running in the computing devices, computer processors, or programmable logic devices can readily be prepared by practitioners skilled in the software or electronic art based on the teachings of the present disclosure.

The system may include computer storage media, transient and non-transient memory devices having computer instructions or software codes stored therein, which can be used to program or configure the computing devices, computer processors, or electronic circuitries to perform any of the processes of the present invention. The storage media, transient and non-transient memory devices can include, but are not limited to, floppy disks, optical discs, Blu-ray Disc, DVD, CD-ROMs, and magneto-optical disks, ROMs, RAMs, flash memory devices, or any type of media or devices suitable for storing instructions, codes, and/or data.

The system may also be configured as distributed computing environments and/or Cloud computing environments, wherein the whole or portions of machine instructions are executed in distributed fashion by one or more processing devices interconnected by a communication network, such as an intranet, Wide Area Network (WAN), Local Area Network (LAN), the Internet, and other forms of data transmission medium.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated.

1. A system for photovoltaic I-V curve tracing, comprising:
a measurement module providing a platform for connecting a photovoltaic (PV) panel module for current and voltage measurement using an electronic load, wherein the measurement module comprises a voltage sensor, a current sensor, and a metal-oxide-semiconductor field-effect transistor (MOSFET) serving as the electronic load, the PV panel module and the current sensor are connected in series, and a series combination of the PV panel module and the current sensor is connected in parallel with the voltage sensor as well as the MOSFET;
an industrial I/O expansion module coupled with the measurement module for conversion of analog signals to digital signals;
a single-board computer (SBC) module configured to obtain current and voltage readings from the measurement module via the industrial I/O expansion module; and
a user interface module coupled with the SBC module and providing a user interface, allowing at least one user to operate a measurement process and obtain visual measurement results.

2. The system of claim 1, wherein the MOSFET has a gate coupled with a gate-source voltage supply and a source coupled with a ground potential terminal, wherein the measurement module further comprises a resistor of 100 kΩ connected in parallel with the gate and the source of the MOSFET.

3. The system of claim 2, wherein the MOSFET has a drain coupled with a positive terminal of the PV panel module, the source of the MOSFET is coupled with a negative terminal of the PV panel module, and wherein the measurement module further comprises a capacitor of 100 uF, and the drain and the source of the MOSFET are connected in parallel with the capacitor.

4. The system of claim 1, wherein the MOSFET has a gate-source voltage range of ±20 V, a maximum drain-source voltage of 100V, and a continuous drain current restricted to 5.6A at a temperature of 25° C. and limited to 4.0A at a temperature of 100° C.

5. The system of claim 1, wherein the MOSFET is a N-channel MOSFET.

6. The system of claim 1, wherein thee measurement module further comprises a sense resistor of 1500 Ω and a ground resistor of 100Ω, and the voltage sensor is coupled to a negative voltage pole of the PV panel module via the sense resistor and to a ground potential terminal via the ground resistor.

7. The system of claim 1, wherein the industrial I/O expansion module applies an industrial automation I/O card which offers four analogue inputs with a range of 0-10V or ±10V, as well as four analogue outputs with a range of 0-10 V.

8. The system of claim 7, wherein the industrial I/O expansion module is further configured to collect data of 0-10V or ±10V analog inputs from the voltage sensor and the current sensor of the measurement module, and the industrial I/O expansion module is further configured to produce a sawtooth wave with a voltage range of 3-5V as one or more sweeping signals to generate a gate-source voltage for the MOSFET.

9. The system of claim 8, wherein the industrial I/O expansion module is further configured to produce a step in the sweeping signals of 0.01V for the MOSFET.

10. The system of claim 1, wherein the user interface module is further configured to:
display the visual measurement results comprising a graph with a plotting of I-V and P-V curves for the PV panel module, wherein curves for characteristics of the MOSFET at different gate-source voltages are present on the graph.

11. A method for arranging a system for photovoltaic I-V curve tracing, comprising:
providing a measurement module providing a platform for connecting a photovoltaic (PV) panel module for current and voltage measurement using an electronic load, wherein the measurement module comprises a voltage sensor, a current sensor, and a metal-oxide-semiconductor field-effect transistor (MOSFET) serving as the electronic load;
connecting the PV panel module and the current sensor in series;
connecting a series combination of the PV panel module and the current sensor in parallel with the voltage sensor as well as the MOSFET;
coupling an industrial I/O expansion module with the measurement module for conversion of analog signals to digital signals;
coupling a single-board computer (SBC) module with the industrial I/O expansion module such that the SBC module is able to obtain current and voltage readings from the measurement module via the industrial I/O expansion module; and
coupling a user interface module with the SBC module, such that the user interface module is able to provide a user interface, allowing at least one user to operate a measurement process and obtain visual measurement results.

12. The method of claim 11, wherein the MOSFET has a gate coupled with a gate-source voltage supply and a source coupled with a ground potential terminal, wherein the measurement module further comprises a resistor of 100 kΩ connected in parallel with the gate and the source of the MOSFET.

13. The method of claim 12, wherein the MOSFET has a drain coupled with a positive terminal of the PV panel module, the source of the MOSFET is coupled with a negative terminal of the PV panel module, and wherein the measurement module further comprises a capacitor of 100 uF, and the drain and the source of the MOSFET are connected in parallel with the capacitor.

14. The method of claim 11, wherein thee measurement module further comprises a sense resistor of 1500 Ω and a ground resistor of 100Ω, and the voltage sensor is coupled to a negative voltage pole of the PV panel module via the sense resistor and to a ground potential terminal via the ground resistor.

15. The method of claim 11, wherein the industrial I/O expansion module applies an industrial automation I/O card which offers four analogue inputs with a range of 0-10V or ±10V, as well as four analogue outputs with a range of 0-10 V.

16. A method for photovoltaic I-V curve tracing, comprising:
providing the system of claim 1; and
displaying the visual measurement results comprising a graph with a plotting of I-V and P-V curves for the PV panel module.

17. The method of claim 16, wherein the displaying the visual measurement results comprises displaying curves for characteristics of the MOSFET at different gate-source voltages are present on the graph.
